(19) United States
(12) Patent Application Publication
(10) Pub. No.: US 2009/0181508 A1
(43) Pub. Date: Jul. 16, 2009

(54) Method and Structure For NFET With Embedded Silicon Carbon

(75) Inventors: Judson R. Holt, Wappingers Falls, NY (US); Yaocheng Liu, White Plains, NY (US); Kern Rim, Yorktown Heights, NY (US)

Correspondence Address: FREDERICK W. GIBB, III;Gibb Intellectual Property Law Firm, LLC, 2568-A RIVA ROAD, SUITE 304, ANNAPOLIS, MD, 21401, US

(73) Assignee: International Business Machines Corporation, Armonk, NY (US)

(21) Appl. No.: 12/014,934

(22) Filed: Jan. 16, 2008

(51) Int. Cl. H01L 21/336

(52) U.S. Cl. 438/285; 257/E21.409

(57) ABSTRACT

A method forms a gate stack over a channel region of a substrate and then forms disposable spacers on sides of the gate stack. Trenches are then recessed in regions of the substrate not protected by the gate stack and the disposable spacers. Carbon-doped Silicon lattice structures are then formed in the trenches. During the forming of the Carbon-doped Silicon lattice structures Carbon atoms can be positioned in any substitutional sites within the lattice structures. The Carbon-doped Silicon lattice structures are then amorphized by implantation of an amorphizing species. An annealing process then recrystallizes the amorphized regions by solid-phase epitaxy regrowth to form the source and drain regions. During the annealing, a majority of Carbon atoms are substitutionally incorporated into a Silicon lattice of the source and drain regions to provide tensile stress to the channel region.

### BACKGROUND AND SUMMARY

The embodiments of the invention generally relate to integrated circuit structures and more particularly to a method of forming a transistor structure that utilizes recrystallized amorphized (by solid-phase epitaxy regrowth) source and drain regions to create tensile stress in the channel of the transistor.

In one embodiment, the invention comprises a method of forming a field effect transistor (FET), such as an N-type FET (NFET). The method first forms a gate stack over a channel region of a substrate and then forms disposable spacers on sides of the gate stack. The disposable spacers define the distance between the subsequently formed source/drain regions and the channel. Trenches are then recessed in regions of the substrate not protected by the gate stack and the disposable spacers.

Carbon-doped Silicon lattice structures are then formed in the trenches. During the forming of the Carbon-doped Silicon lattice structures, Carbon atoms can be positioned in any substitutional or interstitial sites within the lattice structures. The Carbon-doped Silicon lattice structures are then amorphized by implantation of an amorphizing species. The amorphizing species comprises one of or combination of (but not limited to): Silicon; Germanium; Arsenic; and Xenon. An annealing process then recrystallizes the amorphized regions by solid-phase epitaxy regrowth to form the source and drain regions. During the annealing, a majority of Carbon atoms are substitutionally incorporated into a Silicon lattice of the source and drain regions to provide tensile stress to the channel region.

These and other aspects of the embodiments of the invention will be better appreciated and understood when considered in conjunction with the following description and the accompanying drawings. It should be understood, however, that the following descriptions, while indicating embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a schematic cross-sectional diagram of a field effect transistor;

FIG. 2 is a schematic cross-sectional diagram of a field effect transistor;

FIG. 3 is a schematic cross-sectional diagram of a field effect transistor;

FIG. 4 is a schematic cross-sectional diagram of a field effect transistor; and

FIG. 5 is a schematic cross-sectional diagram of a field effect transistor.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

It is well known that tensile strain can improve the channel electron mobility of N-type metal oxide semiconductor field effect transistors (N-MOSFETs) but the formation of the tensile strain is not trivial. One idea is to utilize Carbon-doped Silicon (Si:C) which has a smaller lattice constant than Silicon to “pull” the channel from the source/drain regions. A substitutional Carbon concentration of approximately 2% by atomic weight (˜2 at. %) or higher is needed in order to obtain reasonable improvement in device performance. However, the equilibrium solid solubility of Carbon in Silicon is very low and it is very difficult to grow Carbon-doped Silicon with high substitutional Carbon concentration.

In general, low-temperature CVD epitaxy is used for Carbon-doped Silicon growth. Low temperature is beneficial for substitutional Carbon incorporation in Silicon lattice. However, the growth rate at low temperatures is too low to be used in real manufacturing. Furthermore, it is also very difficult to get selective growth at low temperatures. If high temperatures are used for the Carbon-doped Silicon CVD epi growth, it can solve the deposition rate and selectivity problems, but the Carbon atoms may not be completely incorporated into the Silicon lattice. Instead, many of the Carbon atoms will be located at the interstitial sites or even form a SiC compound and hence the strain will be very limited, while the interstitial Carbon or SiC compound may degrade device performance.

One idea of this invention is to use solid-phase epitaxy (SPE) to grow the Carbon-doped Silicon alloy in the source/drain regions of N-channel MOSFETs. With this idea, the problem of substitutionally incorporating Carbon into Silicon lattice is decoupled from the problems of depositing Carbon-doped Silicon with high deposition rate and selectivity. Consequently optimized conditions can be used to solve the different problems individually. The CVD deposition of Carbon-doped Silicon becomes very easy without the concern of incomplete substitutional Carbon incorporation. Both high deposition rate and good selectivity can be obtained. On the other hand, the SPE process can be optimized to incorporate Carbon atoms to the Silicon lattice. Another advantage of using this invention is the possibility of achieving metastable Carbon-doped Silicon alloy with substitutional Carbon concentrations that are much higher than Carbon's solid solubility. The N+ doping can also be activated during the Carbon-doped Silicon SPE regrowth.

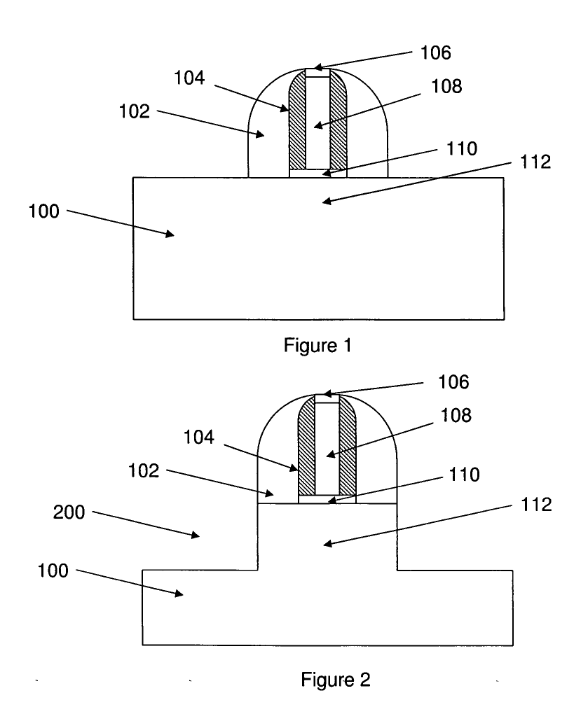

Therefore, as shown in schematic cross-section in FIG. 1, a conventional gate stack is formed. The conventional gate comprises a gate dielectric 110 above a channel region 112 within a substrate 100. A gate conductor 108 is formed above the gate oxide 110 and a gate cap 106 tops the gate conductor 108. Permanent insulating spacers 104 are formed along sides of the gate conductor 108 to protect the gate conductor. For a complete discussion of gate stack formation, see U.S. Patent Publication 2005/0073014, incorporated herein by reference.

After gate stack formation and patterning, disposable spacers 102 are formed on the permanent spacers 104 to define the distance between the subsequently formed Carbon-doped Silicon regions and the channel. Then, as shown in FIG. 2, a recessing reactive ion etch (RIE) is used to etch trenches 200 in regions that will subsequently become source/drain regions (e.g., the regions of said substrate not protected by said disposable spacers).

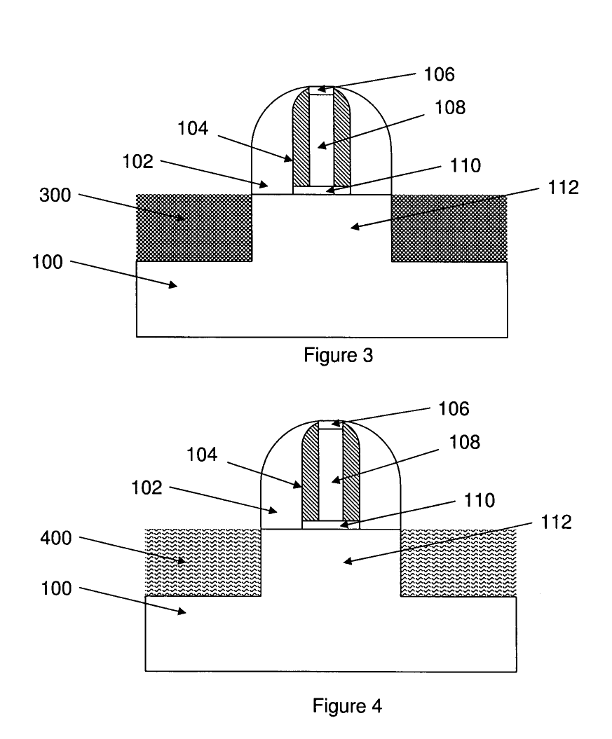

As shown in FIG. 3, selective growth or deposition of Carbon-doped Silicon 300 (with the appropriate required Carbon chemical concentration) is used to fill the trenches. The Carbon concentration will vary, depending upon the design and desired characteristics of the transistor. During this Carbon-doped Silicon deposition, unlike conventional processing, the Carbon atoms can be positioned in any substitutional or interstitial sites of the Silicon lattice. The substitutional or interstitial nature of carbon incorporation will not affect the inventive structure, because during the solid-phase epitaxy (SPE) regrowth, the majority of Carbon atoms are substitutionally incorporated into the Silicon lattice and form the stressor to provide tensile stress to the channel region 112. Further, the crystal quality of the deposited Carbon-doped Silicon does not have to very high because the SPE regrowth substitutionally incorporates the Carbon atoms.

Next, as shown in FIG. 4, the Carbon-doped Silicon regions 300 are amorphized by implantation of Silicon, Germanium, Arsenic, Xenon or other amorphizing species, resulting in amorphized regions 400. Generally part of the Silicon substrate 100 underneath the Carbon-doped Silicon is also amorphized during this implantation. This pre-amorphization implantation can be followed by N+ source/drain implantation (doping) and even the source/drain extension implantation.

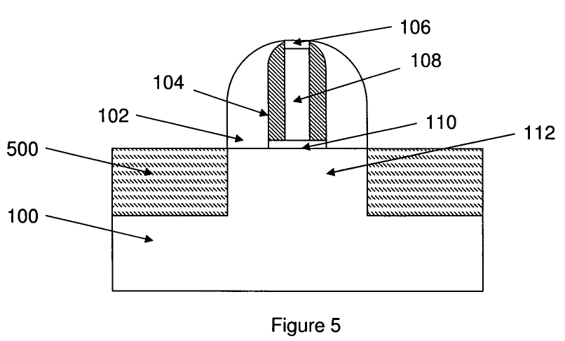

Then, as shown in FIG. 5, the wafers are annealed so that the amorphous Carbon-doped Silicon lattice structures 400 and Silicon 100 are recrystallized by solid-phase epitaxy into the final source and drain regions 500. The anneal is performed at a temperature above the recrystallization point, but below the melting point of the Carbon-doped Silicon lattice structures 400 Different techniques can be used for this annealing step, such as furnace anneal, rapid thermal anneal, flash anneal and laser anneal. For a complete discussion of annealing processes and other gate stack formation processes, see U.S. Patent Publication 2007/0238267, incorporated herein by reference. During the SPE regrowth, the majority of Carbon atoms are substitutionally incorporated into the Silicon lattice and form the stressor to provide tensile stress to the channel region 112. At the same time, the N type doping in the source/drain regions can also be activated.

Thus, as shown above, the invention uses solid-phase epitaxy (SPE) to grow the Carbon-doped Silicon alloy in the source/drain regions of N-channel MOSFETs. The inventive method decouples the problem of substitutionally incorporating Carbon into the Silicon lattice from the problems of depositing Carbon-doped Silicon with high deposition rate and selectivity. Consequently, optimized conditions can be used to solve the different problems individually. The CVD deposition of Carbon-doped Silicon becomes very easy when it is done without the concern of substitutional Carbon incorporation. Both high deposition rate and good selectivity can be obtained when the Carbon atoms can be positioned in any substitutional sites of the Silicon lattice. On the other hand, the annealing (SPE) process can be optimized to incorporate Carbon atoms to the Silicon lattice. Another advantage of using this invention is the possibility of achieving metastable Carbon-doped Silicon alloy with substitutional Carbon concentrations that are much higher than Carbon's solid solubility.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of embodiments, those skilled in the art will recognize that the embodiments of the invention can be practiced with modification within the spirit and scope of the appended claims.

What is claimed is:

1. A method of forming a structure comprising:
forming a gate stack over a channel region of a substrate;
recessing trenches in regions of said substrate adjacent said gate stack;
forming Carbon-doped Silicon lattice structures in said trenches, wherein during said forming of said Carbon-doped Silicon lattice structures Carbon atoms can be positioned in any substitutional or interstitial sites within said lattice structures;
amorphizing said Carbon-doped Silicon lattice structures by implantation of an amorphizing species to produce amorphized regions; and
annealing said structure to recrystallize said amorphized regions by solid-phase epitaxy regrowth into source and drain regions.

2. The method according to claim 1, all the limitations of which are incorporated herein by reference, wherein during said annealing, a majority of Carbon atoms are substitutionally incorporated into said Carbon-doped Silicon lattice of said source and drain regions to provide tensile stress to said channel region.

3. The method according to claim 1, all the limitations of which are incorporated herein by reference, wherein said amorphizing species comprises one of: Silicon; Germanium; Arsenic; and Xenon.

4. A method of forming a structure comprising:
forming a gate stack over a channel region of a substrate;
forming disposable spacers on sides of said gate stack;
recessing trenches in regions of said substrate not protected by said gate stack and said disposable spacers;
forming Carbon-doped Silicon lattice structures in said trenches, wherein during said forming of said Carbon-doped Silicon lattice structures Carbon atoms can be positioned in any substitutional or interstitial sites within said lattice structures;
amorphizing said Carbon-doped Silicon lattice structures by implantation of an amorphizing species to produce amorphized regions; and
annealing said structure to recrystallize said amorphized regions by solid-phase epitaxy regrowth into source and drain regions,
wherein said disposable spacers define a distance between said source drain regions and said channel region.

5. The method according to claim 4, all the limitations of which are incorporated herein by reference, wherein during said annealing, a majority of Carbon atoms are substitutionally incorporated into said Carbon-doped Silicon lattice of said source and drain regions to provide tensile stress to said channel region.

6. The method according to claim 4, all the limitations of which are incorporated herein by reference, wherein said amorphizing species comprises one of: Silicon; Germanium; Arsenic; and Xenon.
